(19) United States
(12) Patent Application Publication
(10) Pub. No.: US 2025/0210443 A1
(43) Pub. Date: Jun. 26, 2025

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventor: Yasuhiro SAKAI, Tokyo (JP)

(73) Assignee: Mitsubishi Electric Corporation, Tokyo (JP)

(21) Appl. No.: 18/849,745

(22) PCT Filed: Apr. 25, 2022
(86) PCT No.: PCT/JP2022/018709

§ 371 Date: Sep. 23, 2024

(51) Int. Cl. H01L 23/367; H01L 21/48; H01L 23/00; H01L 23/498; H01L 25/07

(52) U.S. Cl. CPC H01L 23/367; H01L 21/4853; H01L 21/4871; H01L 23/49811; H01L 24/32; H01L 25/072; H01L 24/48; H01L 2224/32227; H01L 2224/32238; H01L 2224/48159; H01L 2924/38

(57) ABSTRACT

A semiconductor device includes: a heat sink; an insulating substrate; a bonding material; and a semiconductor element, wherein the insulating substrate is bonded to an upper surface of the heat sink through the bonding material, the semiconductor element is bonded to an upper surface of the insulating substrate, a thickness of the heat sink differs depending on a position of the heat sink in the in-plane direction, supporters are disposed on the upper surface of the heat sink, in a region in which the insulating substrate is bonded to the heat sink, and each of the supporters is in contact with the insulating substrate, and the upper surface of the heat sink is not parallel to the upper surface of the insulating substrate, in a region overlapping with the region in which the insulating substrate is bonded to the heat sink in a plan view.

### TECHNICAL FIELD

The present disclosure relates to a semiconductor device and a method of manufacturing the semiconductor device.

### BACKGROUND ART

Patent Document 1 proposes a device including a mechanism that corrects a slope of an object to be bonded, in tape bonding a semiconductor element that is not horizontally fixed.

### PRIOR ART DOCUMENT

### Patent Document

Patent Document 1: Japanese Patent Application Laid-Open No. 2007-250571

### SUMMARY

### Problem to be Solved by the Invention

In known semiconductor devices each including an insulating substrate bonded to a heat sink, when a thickness of the heat sink differs depending on a position of the heat sink in an in-plane direction, the manufacturing process is troublesome. For example, when the heat sink is fixed to a surface plate of an ultrasonic bonding apparatus, the insulating substrate is sloped to reflect differences in thickness of the heat sink at respective positions of the heat sink in the in-plane direction. This causes a nonuniform contact between the sloped insulating substrate and a terminal pressed against the surface plate of the ultrasonic bonding apparatus in the vertical direction, and creates a problem in that the terminal cannot be pressed at a uniform pressure.

The present disclosure has been conceived to solve the problem, and has an object of providing a semiconductor device which includes an insulating substrate bonded to a heat sink and which can mitigate a problem caused by differences in thickness of the heat sink at the respective positions of the heat sink in the in-plane direction.

### Means to Solve the Problem

A semiconductor device according to the present disclosure includes: a heat sink; an insulating substrate; a bonding material; and a semiconductor element, wherein the insulating substrate is bonded to an upper surface of the heat sink through the bonding material, the semiconductor element is bonded to an upper surface of the insulating substrate, a thickness of the heat sink differs depending on a position of the heat sink in an in-plane direction, a plurality of supporters is disposed on the upper surface of the heat sink, in a region in which the insulating substrate is bonded to the heat sink, each of the supporters is in contact with the insulating substrate, and the upper surface of the heat sink is not parallel to the upper surface of the insulating substrate, in a region overlapping with the region in which the insulating substrate is bonded to the heat sink in a plan view.

### Effects of the Invention

The present disclosure provides a semiconductor device which includes an

insulating substrate bonded to a heat sink and which can mitigate a problem caused by differences in thickness of the heat sink at the respective positions of the heat sink in the in-plane direction.

The objects, features, aspects, and advantages related to the technology disclosed in the DESCRIPTION will become more apparent from the following detailed description and the accompanying drawings.

### BRIEF DESCRIPTION OF DRAWINGS

FIG. 1 illustrates a semiconductor device according to Embodiment 1.

FIG. 2 illustrates an in-progress state of producing the semiconductor device according to Embodiment 1.

FIG. 3 is an enlarged view of a part of the semiconductor device in FIG. 1 according to Embodiment 1.

FIG. 4 is an enlarged view of a part of a semiconductor device according to Embodiment 2.

FIG. 5 is an enlarged view of a part of a semiconductor device according to Embodiment 3.

FIG. 6 is a flowchart illustrating a method of manufacturing the semiconductor device according to Embodiment 1.

### DESCRIPTION OF EMBODIMENTS

### A. Embodiment 1

### [A-1. Structure]

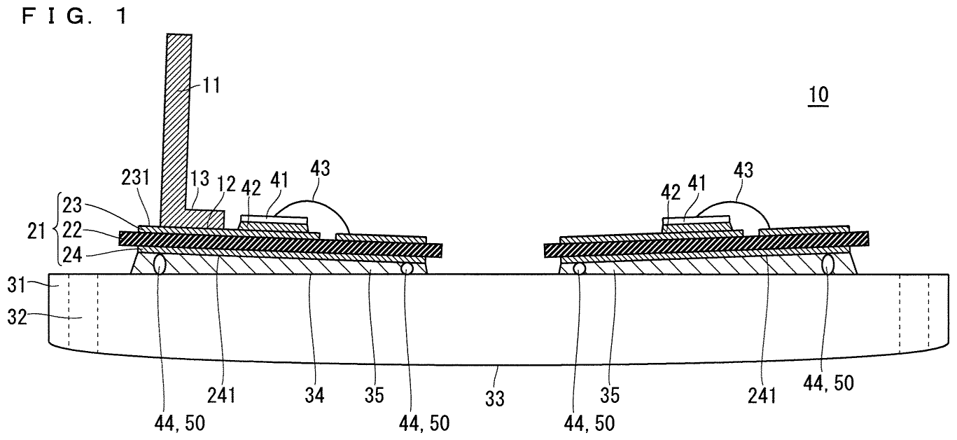

FIG. 1 illustrates a semiconductor device 10 according to Embodiment 1.

As illustrated in FIG. 1, the semiconductor device 10 includes a terminal 11, insulating substrates 21, a heat sink 31, a bonding material 35, semiconductor elements 41, a bonding material 42, wire 43, and a plurality of supporters 50.

Each of the insulating substrates 21 includes an insulating layer 22, and conductor patterns 23 and 24.

The conductor pattern 23 is disposed on an upper surface of the insulating layer 22. The conductor pattern 24 is disposed on a lower surface of the insulating layer 22.

A material of the insulating layer 22 is, for example, silicon nitride, aluminum nitride, or alumina.

Each material of the conductor patterns 23 and 24 is, for example, copper, aluminum, a copper alloy, or an aluminum alloy.

The insulating substrate 21 is bonded to the heat sink 31 through the bonding material 35. A lower surface 241 of the conductor pattern 24 is bonded to an upper surface 34 of the heat sink 31 through the bonding material 35. The bonding material 35 is, for example, solder or a sintered material.

Each of the semiconductor elements 41 is bonded to an upper surface of the conductor pattern 23 through the bonding material 42. The bonding material 42 is, for example, solder or a sintered material.

The terminal 11 is bonded to the conductor pattern 23. Power is supplied from outside the semiconductor device 10 to the semiconductor element 41 through the terminal 11.

The heat sink 31 includes screw holes 32. The screw holes 32 are screw holes for fastening the heat sink 31 to, for example, fins or a surface plate through screws.

A material of the heat sink 31 is, for example, copper, aluminum, a copper alloy, or an aluminum alloy. The material of the heat sink 31 may be a composite material. The composite material is, for example, AlSiC or MgSiC.

The thickness of the heat sink 31 differs depending on a position of the heat sink 31 in an in-plane direction.

The thickness of the heat sink 31 ranges, for example, from 3 mm to 8 mm.

For example, the center of the heat sink 31 is the thickest in a plan view. The following will be described assuming this case.

The heat sink 31 is thinned, for example, from the center of the heat sink 31 toward the circumferential direction at a rate of 0.1 mm to 0.5 mm per 100 mm.

The upper surface 34 of the heat sink 31 is, for example, a plane in a state where the heat sink 31 is not fastened to, for example, fins or a surface plate and a lower surface 33 of the heat sink 31 is not pressed to another element (hereinafter referred to as a “non-fastening state”).

In the non-fastening state, the lower surface 33 of the heat sink 31 is, for example, a curved surface protruding downward.

In the non-fastening state, a center portion of the heat sink 31 is located below a perimeter of the heat sink 31, in the lower surface 33 of the heat sink 31.

For example, the center of the heat sink 31 is the lowest in a plan view, in the lower surface 33 of the heat sink 31 in the non-fastening state.

The lower surface 33 of the heat sink 31 is, for example, displaced upward from the center of the heat sink 31 toward the circumferential direction in a plan view at a rate of 0.1 mm to 0.5 mm per 100 mm in the non-fastening state. In other words, the lower surface 33 of the heat sink 31 has, for example, a slope approximately ranging from 0.06° to 0.3°.

The lower surface 33 of the heat sink 31 has a shape formed by, for example, partially extracting a spherical surface.

For example, when the semiconductor device 10 is attached to cooling fins of an inverter, pressing the lower surface 33 that is a curved surface protruding downward against the cooling fins can spread out grease between the heat sink 31 and the cooling fins and, for example, thin the grease to approximately several tens μm. The thermal conductivity of the grease is, for example, as low as approximately several W/mK. Thus, thinning the grease in this manner improves heat dissipation.

It is conceivable to use, instead of the heat sink 31, a heat sink obtained by warping a flat plate, that is, a plate with a constant thickness in an in-plane direction to have a curved lower surface protruding downward. However, the heat sink 31 can spread out grease thinner with a higher pressure and increase the heat dissipation more than the heat sink obtained by warping the flat plate.

Each of the supporters 50 is disposed in a region in which the insulating substrate 21 is bonded through the bonding material 35 on the upper surface 34 of the heat sink 31. Each of the supporters 50 in Embodiment 1 is a spacer 44. The spacer 44 is formed of, for example, an aluminum wire as a material.

Each of the supporters 50 is in contact with the heat sink 31 and the insulating substrate 21. Thus, a slope of the insulating substrate 21 with respect to the heat sink 31 is defined by a height of each of the supporters 50.

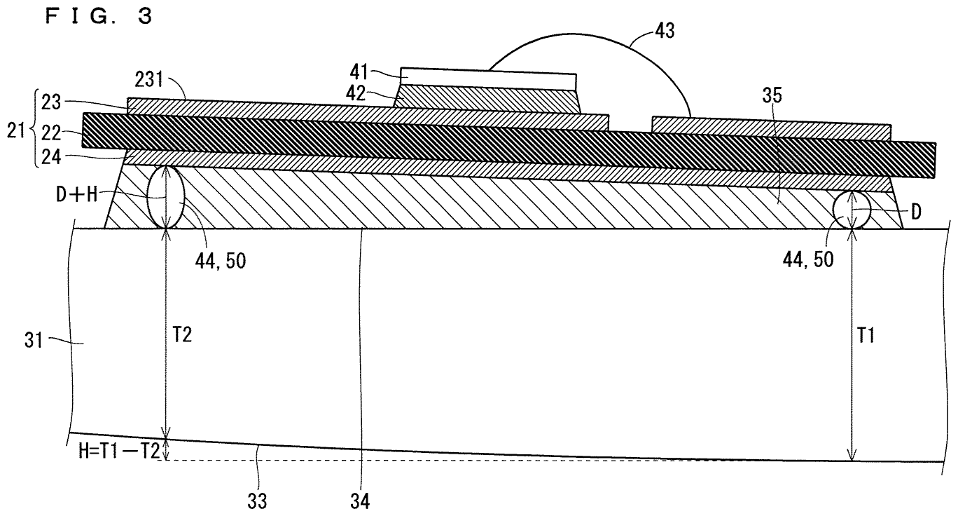

FIG. 3 is an enlarged view of a part of the semiconductor device 10 in FIG. 1.

It is assumed that T1 denotes a thickness of the heat sink 31 at a position of the supporter 50 disposed the closest to the center of the heat sink 31 in a plan view (hereinafter referred to as a supporter 50a), and D denotes a height of the supporter 50a. A height of each of the remaining supporters 50 is expressed by, for example, D+H, assuming a difference between the thickness T1 and a thickness T2 of the heat sink 31 at a position of the supporter 50 as H (H=T1−T2). This makes distances from the lower surface 33 of the heat sink 31 at the respective positions of the supporters 50 to the upper ends of the supporters 50 equal to one another. Thereby, when the lower surface 33 of the heat sink 31 is pressed against a mounting surface of a surface plate to deform the heat sink 31 and flatten the lower surface 33, the mounting surface of the surface plate becomes parallel to an upper surface 231 of the insulating substrate 21. Here, the upper surface 231 of the insulating substrate 21 is the upper surface of the conductor pattern 23.

A height of each of the supporters 50 except the supporter 50a is, for example, higher than or equal to D+0.9×H and lower than or equal to D+1.1×H, assuming the difference between the thickness T1 and the thickness T2 of the heat sink 31 at a position of the supporter 50 as H (H=T1−T2).

Increasing the height of a first supporter that is the supporter 50 disposed at a position at which the heat sink 31 is thinner more than that of a second supporter that is the supporter 50 disposed at a position at which the heat sink 31 is thicker mitigates the influence on the differences in thickness of the heat sink 31 at the respective positions of the heat sink 31 in the in-plane direction.

Since the thickness of the heat sink 31 differs depending on the position of the heat sink 31 in the in-plane direction, the lower surface 33 of the heat sink 31 is not parallel to the upper surface 231 of the insulating substrate 21 in the absence of the supporters 50. Thus, in the absence of the supporters 50 and when the heat sink 31 is fastened to, for example, fins or a surface plate, that is, when the lower surface 33 of the heat sink 31 is pressed against a mounting surface of a stage that is a plane, the upper surface 231 of the insulating substrate 21 is not parallel to the mounting surface of the stage.

Since the semiconductor device 10 according to Embodiment 1 includes the plurality of supporters 50, the upper surface 34 of the heat sink 31 is not parallel to the upper surface 231 of the insulating substrate 21 in a region overlapping with a region in which the insulating substrate 21 is bonded to the heat sink 31 in a plan view. The plurality of supporters 50 are disposed such that the lower surface 33 of the heat sink 31 and the upper surface 231 of the insulating substrate 21 are closer to being parallel than the upper surface 34 of the heat sink 31 and the upper surface 231 of the insulating substrate 21 in the region overlapping with the region in which the insulating substrate 21 is bonded to the heat sink 31 in a plan view. Thus, when the lower surface 33 of the heat sink 31 is pressed against a mounting surface of a stage that is a plane, for example, a mounting surface of a surface plate, the upper surface 231 of the insulating substrate 21 and the plane are closer to being parallel than those in the absence of the supporters 50. Consequently, when the terminal 11 is bonded to the conductor pattern 23 of the insulating substrate 21, for example, when the terminal 11 is ultrasonic-bonded to the conductor pattern 23 of the insulating substrate 21, the vertical force to be added to the terminal 11 is more uniformly transmitted to a contact surface between the terminal 11 and the conductor pattern 23, which improves the quality of bonding of the terminal 11 to the conductor pattern 23. For example, a bonding surface 12 of the terminal 11 is fully and tightly bonded to the upper surface 231 of the insulating substrate 21. As such, the semiconductor device 10 is a semiconductor device capable of mitigating a problem caused by differences in thickness of the heat sink at respective positions of the heat sink in the in-plane direction.

When the insulating substrate 21 is sloped, it is conceivable to correct a direction of the force to be added to the terminal 11 according to the slope using a sensor that measures the slope of the insulating substrate 21. However, when a foreign substance such as metal powder adheres to a portion to be measured by the sensor, a problem in that the correction function does not properly work may arise. When the semiconductor device according to Embodiment 1 is produced, the problem caused by the slope of the insulating substrate 21 can be reduced without using the sensor that measures the slope of the insulating substrate 21. It is to be noted, however, that when the semiconductor device according to Embodiment 1 is produced, the correction based on the measurement of the slope of the insulating substrate 21 using the sensor that measures the slope of the insulating substrate 21 can further reduce the influence by the slope of the insulating substrate 21 overall.

### [A-2. Manufacturing Method]

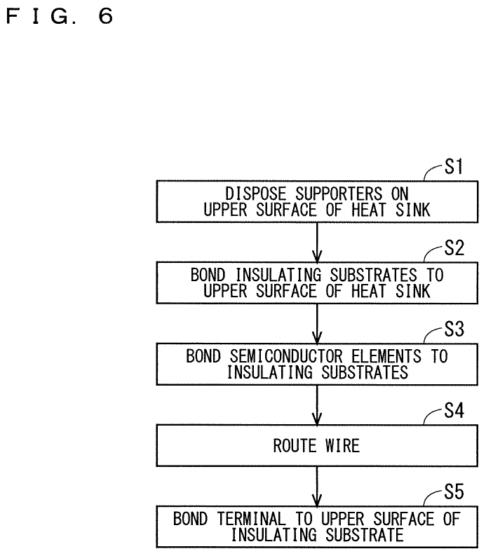

FIG. 6 is a flowchart illustrating a method of manufacturing the semiconductor device according to Embodiment 1. The method of manufacturing the semiconductor device according to Embodiment 1 includes Steps S1 to S5.

First, in Step S1, the supporters 50 are disposed on the upper surface 34 of the heat sink 31.

Next, in Step S2, the insulating substrates 21 are bonded to the upper surface 34 of the heat sink 31 through the bonding material 35.

Next, in Step S3, the semiconductor elements 41 are bonded to the insulating substrates 21 through the bonding material 42.

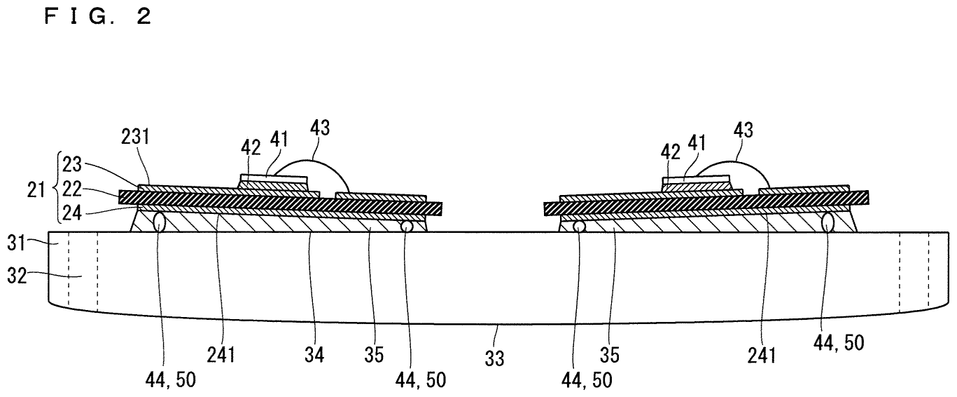

Next, in Step S4, the wire 43 is routed (see FIG. 2).

Next, in Step S5, the terminal 11 is ultrasonic-bonded to the upper surface 231 of the insulating substrate 21 from a state illustrated in FIG. 2. This produces the semiconductor device 10 in FIG. 1. In Step S5, the heat sink 31 is fixedly fastened to a surface plate of an ultrasonic bonding apparatus through screws. The ultrasonic bonding apparatus performs the ultrasonic-bonding with the lower surface 33 of the heat sink 31 being pressed against the mounting surface of the surface plate that is a plane. The ultrasonic bonding apparatus performs the ultrasonic-bonding with an ultrasonic-bonding tool being pressed against an ultrasonic-bonding tool pressing surface 13 of the terminal 11.

### B. Embodiment 2

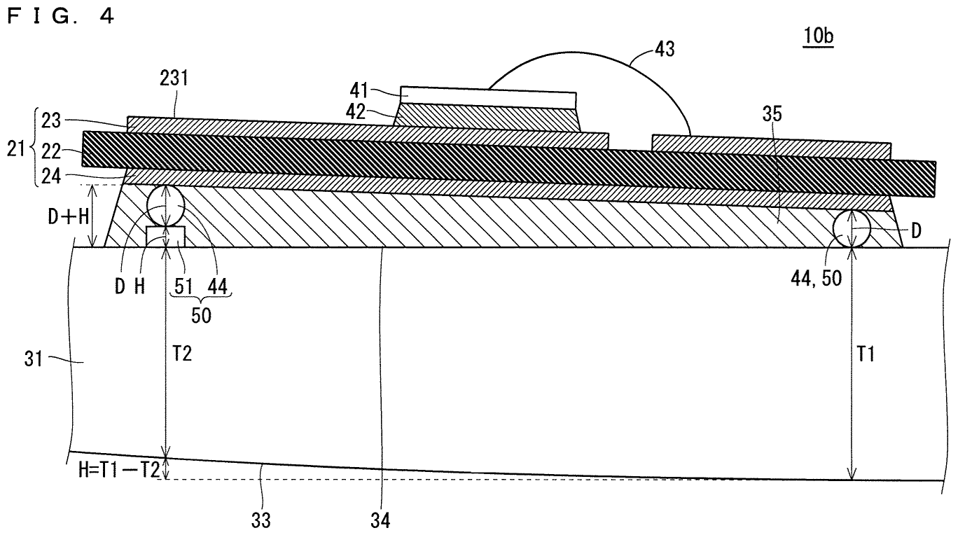

FIG. 4 is an enlarged view of a part of a semiconductor device 10b according to Embodiment 2, and is a view corresponding to FIG. 3 according to Embodiment 1.

In the semiconductor device 10b, at least a part of the plurality of supporters 50 each include a spacer 44, and a protrusion 51 integrally formed with the heat sink 31 on the upper surface of the heat sink 31. The semiconductor device 10b is identical to the semiconductor device 10 in other respects.

Since the semiconductor device 10b also includes the plurality of supporters 50 similarly to the semiconductor device 10 according to Embodiment 1, the upper surface 34 of the heat sink 31 is not parallel to the upper surface 231 of the insulating substrate 21 in a region overlapping with a region in which the insulating substrate 21 is bonded to the heat sink 31 in a plan view. The plurality of supporters 50 are disposed such that the lower surface 33 of the heat sink 31 and the upper surface 231 of the insulating substrate 21 are closer to being parallel than the upper surface 34 of the heat sink 31 and the upper surface 231 of the insulating substrate 21 in the region overlapping with the region in which the insulating substrate 21 is bonded to the heat sink 31 in a plan view.

Although the supporter 50 disposed the closest to the center of the heat sink 31 in a plan view (hereinafter referred to as the supporter 50a) is, for example, the spacer 44 without any protrusion as illustrated in FIG. 4, the supporter 50a may include the spacer 44, and the protrusion 51 integrally formed with the heat sink 31 on the upper surface of the heat sink 31.

It is assumed that T1 denotes a thickness of the heat sink 31 at a position of the supporter 50a, and D denotes a height of the supporter 50a. For example, the protrusion 51 of a height of a difference H between the thickness T1 and the thickness T2 of the heat sink 31 at a position of each of the remaining supporters 50 (H=T1−T2) is formed at the position of the supporter 50. The supporter 50 includes this protrusion 51, and the spacer 44 of the height D which is disposed on the protrusion 51. Thereby, when the lower surface 33 of the heat sink 31 is pressed against a mounting surface of a surface plate to deform the heat sink 31 and flatten the lower surface 33, the mounting surface of the surface plate becomes parallel to an upper surface of the insulating substrate 21. Thus, changing the height of each of the protrusions 51 according to the position of the supporter 50 in the semiconductor device 10b enables use of the spacers 44 with the same height in the supporters 50. Thus, the cost of the spacers 44 can be reduced. Here, the use of the spacers 44 with the same height in the supporters 50 means that the height of the highest spacer 44 is 1.05 times of that of the lowest spacer 44 from among the spacers 44 to be used in the plurality of supporters 50.

The heights of the spacers 44 included in the supporters 50 may be different from one another.

The protrusions 51 are formed by, for example, press working.

### C. Embodiment 3

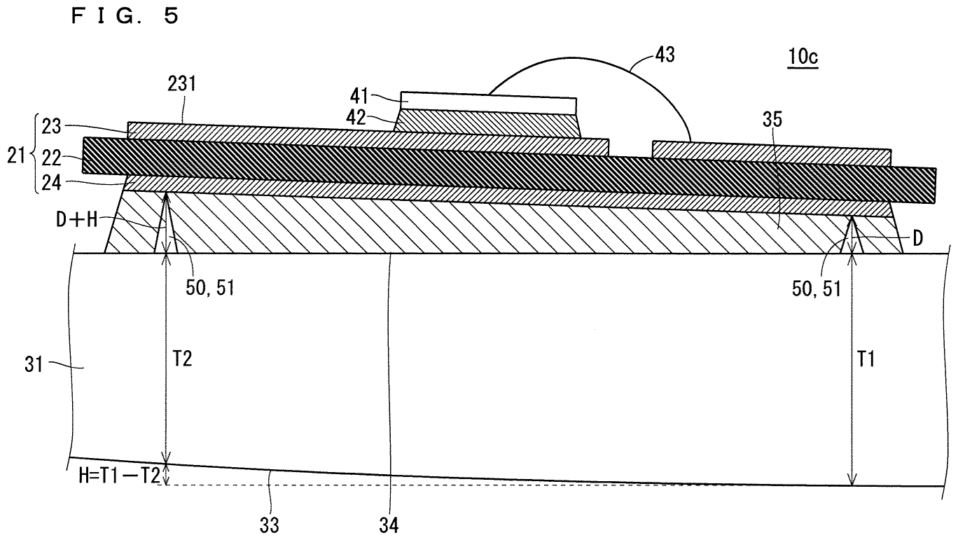

FIG. 5 is an enlarged view of a part of a semiconductor device 10c according to Embodiment 3, and is a view corresponding to FIG. 3 according to Embodiment 1.

In the semiconductor device 10c, the plurality of supporters 50 are the protrusions 51 integrally formed with the heat sink 31 on the upper surface of the heat sink 31. The semiconductor device 10c is identical to the semiconductor device 10 in other respects.

Since the semiconductor device 10c also includes the plurality of supporters 50 similarly to the semiconductor device 10 according to Embodiment 1, the upper surface 34 of the heat sink 31 is not parallel to the upper surface 231 of the insulating substrate 21 in a region overlapping with a region in which the insulating substrate 21 is bonded to the heat sink 31 in a plan view. The plurality of supporters 50 are disposed such that the lower surface 33 of the heat sink 31 and the upper surface 231 of the insulating substrate 21 are closer to being parallel than the upper surface 34 of the heat sink 31 and the upper surface 231 of the insulating substrate 21 in the region overlapping with the region in which the insulating substrate 21 is bonded to the heat sink 31 in a plan view.

In the semiconductor device 10c, the height of each of the supporters 50 is defined, for example, in the following manner. Assuming that T1 denotes a thickness of the heat sink 31 at a position of the supporter 50 disposed the closest to the center of the heat sink 31 in a plan view (hereinafter referred to as the supporter 50a), D denotes a height of the supporter 50a, and H (H=T1−T2) denotes a difference between the thickness T1 and the thickness T2 of the heat sink 31 at the position of each of the remaining supporters 50, for example, the protrusion 51 of a height D+H is formed as the supporter 50 at a position of the remaining supporter 50.

Embodiment 3 does not require a process of disposing spacers.

Embodiments can be freely combined, and appropriately modified or omitted.

### EXPLANATION OF REFERENCE SIGNS

10, 10b, 10c semiconductor device, 11 terminal, 12 bonding surface, 13 ultrasonic-bonding tool pressing surface, 21 insulating substrate, 22 insulating layer, 23, 24 conductor pattern, 31 heat sink, 32 screw hole, 33, 241 lower surface, 34, 231 upper surface, 35 bonding material, 41 semiconductor element, 42 bonding material, 43 wire, 44 spacer, 50 supporter, 51 protrusion.

1. A semiconductor device, comprising:
a heat sink;
an insulating substrate;
a bonding material; and
a semiconductor element,
wherein the insulating substrate is bonded to an upper surface of the heat sink through the bonding material,
the semiconductor element is bonded to an upper surface of the insulating substrate, a thickness of the heat sink differs depending on a position of the heat sink in an in-plane direction,
a plurality of supporters is disposed on the upper surface of the heat sink, in a region in which the insulating substrate is bonded to the heat sink,
each of the supporter is in contact with the insulating substrate, and
the upper surface of the heat sink is not parallel to the upper surface of the insulating substrate, in a region overlapping with the region in which the insulating substrate is bonded to the heat sink in a plan view.

2. The semiconductor device according to claim 1,
wherein a lower surface of the heat sink and the upper surface of the insulating substrate are closer to being parallel than the upper surface of the heat sink and the upper surface of the insulating substrate in the region overlapping with the region in which the insulating substrate is bonded to the heat sink in the plan view.

3. The semiconductor device according to claim 1,
wherein a lower surface of the heat sink is located below a perimeter of the heat sink, in a center portion of the heat sink.

4. The semiconductor device according to claim 1,
wherein a lower surface of the heat sink is a curved surface protruding downward.

5. The semiconductor device according to claim 1,
wherein the heat sink at a position on which a first supporter of the plurality of supporters is disposed is thinner than the heat sink at a position on which a second supporter of the plurality of supporters is disposed, and
the first supporter is higher than the second supporter.

6. The semiconductor device according to claim 1,
wherein each of the supporter is a spacer on the upper surface of the heat sink and in contact with the upper surface of the heat sink.

7. The semiconductor device according to claim 1,
wherein each of the supporter is a supporter being a spacer on the upper surface of the heat sink and in contact with the upper surface of the heat sink, or a supporter including a protrusion integrally formed with the heat sink on the upper surface of the heat sink, and a spacer on the protrusion.

8. The semiconductor device according to claim 7,
wherein the spacers included in the supporters have a same height.

9. The semiconductor device according to claim 1,
wherein each of the supporter is a protrusion integrally formed with the heat sink on the upper surface of the heat sink.

10. The semiconductor device according to claim 1, further comprising
a terminal,
wherein the terminal is ultrasonic-bonded to the upper surface of the insulating substrate.

11. A method of manufacturing the semiconductor device according to claim 1,
wherein the semiconductor device further includes a terminal,
the method comprising
bonding the insulating substrate to the heat sink, then fixing the heat sink to a surface plate of an ultrasonic bonding apparatus, and ultrasonic-bonding the terminal to the upper surface of the insulating substrate.
